(19) United States
(12) Patent Application Publication
(10) Pub. No.: US 2020/0132095 A1
(43) Pub. Date: Apr. 30, 2020

(54) FOOL-PROOF HOUSING

(71) Applicants: INVENTEC (PUDONG) TECHNOLOGY CORPORATION, Shanghai City (CN); INVENTEC CORPORATION, Taipei City (TW)

(72) Inventors: Hsin-Liang CHEN, Taipei City (TW); Chih-Wei CHIANG, Taipei City (TW); Yu Wen LEE, Taipei City (TW)

(73) Assignees: INVENTEC (PUDONG) TECHNOLOGY CORPORATION, Shanghai City (CN); INVENTEC CORPORATION, Taipei City (TW)

(21) Appl. No.: 16/207,106

(22) Filed: Dec. 1, 2018

(30) Foreign Application Priority Data
Oct. 26, 2018 (CN) 201811257072.9

(51) Int. Cl. F16B 1/00; H05K 7/20

(52) U.S. Cl. CPC F16B 1/00; F16B 2001/0092; H05K 7/20172

(57) ABSTRACT

A fool-proof housing is configured for a first mounting piece which includes a first fool-proof recess or a second mounting piece which includes a second fool-proof recess to be disposed thereon. The fool-proof housing includes a casing and a fool-proof element. The fool-proof element includes a fool-proof protrusion. The fool-proof element is movably disposed on the casing and includes a first position and a second position. When the fool-proof element is in the first position, the casing is configured for the first mounting piece to be mounted thereon, and the fool-proof protrusion blocks the second mounting piece from mounted on the casing. When the fool-proof element is in the second position, the casing is configured for the second mounting piece to be mounted thereon, and the fool-proof protrusion blocks the first mounting piece from mounted on the casing.

### CROSS-REFERENCE TO RELATED APPLICATIONS

This non-provisional application claims priority under 35 U.S.C. § 119(a) on Patent Application No(s). 201811257072.9 filed in China on Oct. 26, 2018, the entire contents of which are hereby incorporated by reference.

### BACKGROUND

### 1. Technical Field

This disclosure relates to a fool-proof housing, more particularly to a fool-proof housing applicable for various types of mounting pieces.

### 2. Related Art

Nowadays, the configuration of electronic devices has become much more complicated, and the assembly process thereof has become much more complex, too. If one component is installed either in a wrong direction or a wrong place in an electronic device, it may result in malfunction of the electronic device, even causing damage to the electronic device when in operation.

To prevent such situation from occurring, a conventional fool-proof housing usually has a foolproof design of having matching shape between engaging components. For example, manufacturers may design the housing foolproof by having matching structures on between a mounting piece and the housing. Therefore, operators may install the mounting piece having a matching shape with the structural feature of the housing on the housing, thereby preventing unexpected installation.

### SUMMARY

According to one or more embodiment of this disclosure, a fool-proof housing is configured for a first mounting piece or a second mounting piece to be disposed thereon. The first mounting piece includes a first fool-proof recess, and the second mounting piece includes a second fool-proof recess. The fool-proof housing includes a casing and a fool-proof element. The fool-proof element includes a fool-proof protrusion. The fool-proof element is movably disposed on the casing and the fool-proof element includes a first position and a second position. When the fool-proof element is in the first position, the casing is configured for the first mounting piece to be mounted thereon, the fool-proof protrusion is located in the first fool-proof recess as the first mounting piece is mounted on the casing, and the fool-proof protrusion blocks the second mounting piece from being mounted on the casing. When the fool-proof element is in the second position, the casing is configured for the second mounting piece to be mounted thereon, the fool-proof protrusion is located in the second fool-proof recess as the second mounting piece is mounted on the casing, and the fool-proof protrusion blocks the first mounting piece from being mounted on the casing.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a perspective view of a fool-proof housing in accordance with one embodiment of the disclosure;

FIG. 2 is an exploded view of the fool-proof housing in FIG. 1;

FIG. 3 is a partial and enlarged view of the fool-proof housing in FIG. 2;

FIG. 4 is another partial and enlarged view of the fool-proof housing in FIG. 2;

FIG. 5 shows a partial front view of an upper row of the fool-proof housing in FIG. 1 when a first mounting piece is installed on the fool-proof housing; and

FIG. 6 shows a partial front view of a lower row of the fool-proof housing in FIG. 1 when a second mounting piece is installed on the fool-proof housing.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

The drawings may not be drawn to actual size or scale, some exaggerations may be necessary in order to emphasize basic structural relationships, while some are simplified for clarity of understanding, and the present disclosure is not limited thereto. It is allowed to have various adjustments under the spirit of the present disclosure. In the embodiments and drawings of the specification, terms for describing positions and directions, such as “top”, “bottom”, “left” and “right”, are used to illustrate but limit the present disclosure. The term “substantially” is referred to the complete or nearly complete extent or degree of a structure, which means that it is allowable to have tolerance during manufacturing.

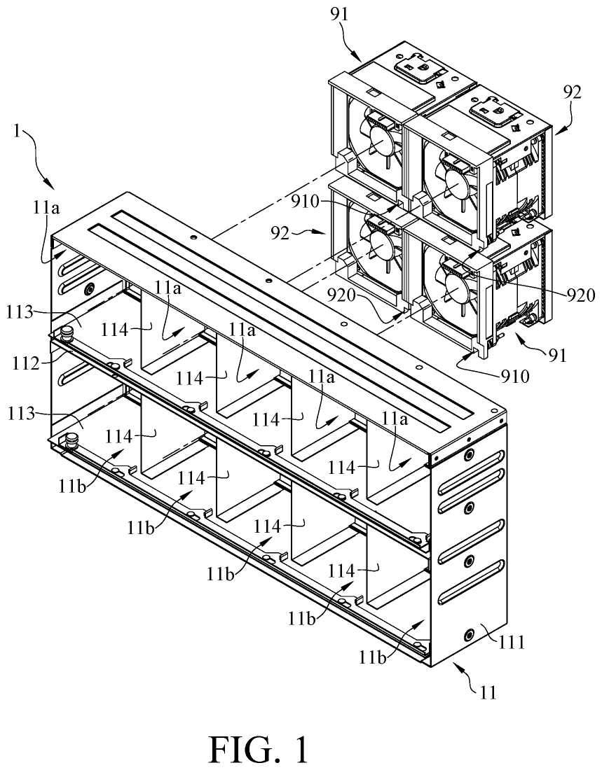

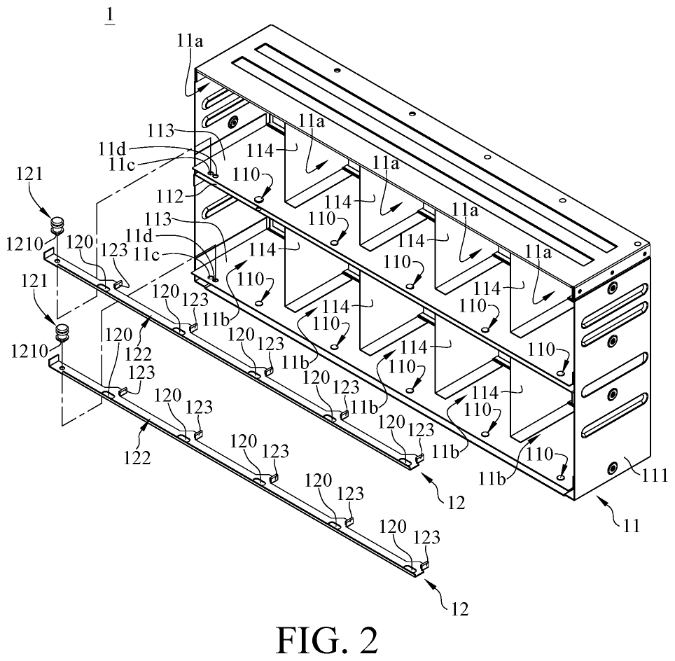

Please refer to FIG. 1 and FIG. 2. FIG. 1 is a perspective view of a fool-proof housing in accordance with one embodiment of the disclosure, and FIG. 2 is an exploded view of the fool-proof housing in FIG. 1.

In this embodiment, a fool-proof housing 1 is provided. The fool-proof housing 1 is configured for the installation of at least one first mounting piece 91 and at least one second mounting piece 92 that may be different in specification. In this or another embodiment, the first mounting piece 91 is, for example, an air-inflow fan, and the second mounting piece 92 is, for example, an air-outflow fan, but the present disclosure is not limited thereto; in some other embodiments, the first mounting piece 91 and the second mounting piece 92 may be other types of mounting pieces that are different or the same in specification. In this embodiment, one of the differences between the first mounting piece 91 and the second mounting piece 92 is that the first mounting piece 91 includes a first fool-proof recess 910 spaced a distance from a side edge of the first mounting piece 91, and the second mounting piece 92 includes a second fool-proof recess 920 connected to a side edge of the second mounting piece 92. In this embodiment, the aforementioned distance is defined as a differential length. The first fool-proof recess 910 and the second fool-proof recess 920 are not limited to be located at the positions described above as long as the difference between the distance from the first fool-proof recess 910 to the side edge of the first mounting piece 91 and a distance from the second fool-proof recess 920 to the side edge of the second mounting piece 92 is equal to the differential length.

In this embodiment, the fool-proof housing 1 includes a casing 11 and two fool-proof elements 12. The casing 11 includes an outer frame 111, a transverse separation plate 112, two transverse carrier plates 113 and eight longitudinal separation plates 114. The transverse separation plate 112 is located in an inner space (not numbered) of the outer frame 111 and divides the inner space into an upper space and a lower space (both not numbered). One of the transverse carrier plates 113 is disposed on the transverse separation plate 112 and located in the upper space. The other transverse carrier plate 113 is disposed on the bottom of the outer frame 111 and located in the lower space. Four of the longitudinal separation plates 114 are spaced apart from each other and disposed on one of the transverse carrier plates 113 and located in the upper space and thus dividing the upper space into five accommodation chambers 11a. The other four of the longitudinal separation plates 114 are spaced apart from each other and disposed on the other transverse carrier plate 113 and located in the lower space and thus dividing the lower space into five accommodation chambers 11b. Note that the present disclosure is not limited to the quantity of the rows of the divided spaces in the outer frame 111 and the quantity of the accommodation chambers in each row. In addition, note that the transverse separation plate, transverse carrier plate and longitudinal separation plate are optional; in other embodiments, the casing may not include the transverse separation plate, transverse carrier plate and longitudinal separation plate, in such a case, the casing only includes one accommodation chamber.

The accommodation chambers 11a may be configured for accommodating the first mounting pieces 91, and the accommodation chambers 11b may be configured for accommodating the second mounting pieces 92. However, the present disclosure is note limited thereto. In other embodiments, the accommodation chambers 11a may be allowed to accommodate the first mounting pieces 91 and second mounting pieces 92 at the same time or to only accommodate the second mounting pieces 92; the accommodation chambers 11b may be allowed to accommodate the first mounting pieces 91 and second mounting pieces 92 at the same time or to only accommodate the first mounting pieces 91.

The casing 11 includes two sets of first fixing hole 11c and second fixing hole 11d. One set of the first fixing hole 11c and the second fixing hole 11d is located on the transverse carrier plate 113 in the upper space, and the other set of the first fixing hole 11c and the second fixing hole 11d is located on the transverse carrier plate 113 in the lower space. The first fixing hole 11c and the second fixing hole 11d of each set are spaced a distance substantially equal to the aforementioned differential distance.

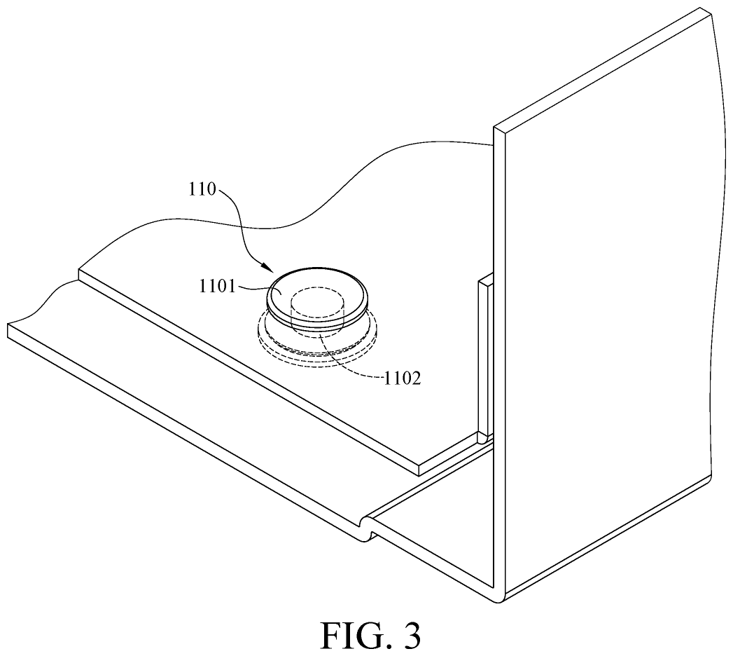

Please also refer to FIG. 3, which is a partial and enlarged view of the fool-proof housing in FIG. 2. The casing 11 includes ten first guiding components 110. Five of the first guiding components 110 are disposed on the transverse carrier plate 113 in the upper space and respectively located in the accommodation chambers 11a. The other five of the first guiding components 110 are disposed on the transverse carrier plate 113 in the lower space and respectively located in the accommodation chambers 11b. Each of the first guiding components 110 includes a head portion 1101 and a neck portion 1102 connected to each other, and the head portion 1101 is connected to the transverse carrier plate 113 via the neck portion 1102.

Each of the fool-proof elements 12 is movable between a first position and a second position relative to the casing 11. Each of the fool-proof elements 12 includes a fixing part 121, a connecting part 122 and five fool-proof protrusions 123. The fixing parts 121 are connected to the fool-proof protrusions 123 via the connecting parts 122 so that the fool-proof protrusions 123 are disposed on the fixing part 121.

The fixing part 121 is configured to be fixed to the casing 11 so that the fool-proof elements 12 can be fixed in position when located in the first position or the second position. Each of the fixing parts 121 includes a fixing protrusion 1210. When the fool-proof elements 12 is in the first position, the fixing protrusion 1210 is disposed through the connecting part 122 and engaged in the first fixing hole 11c of the casing 11. When the fool-proof element 12 is in the second position, the fixing protrusion 1210 is disposed through the connecting part 122 and engaged in the second fixing hole 11d of the casing 11.

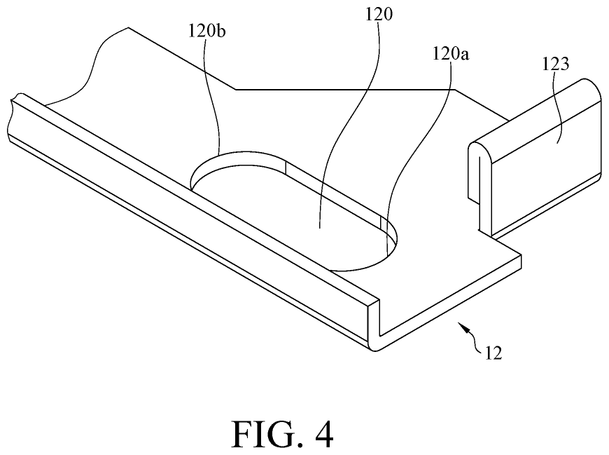

Please also refer to FIG. 4, which is another partial and enlarged view of the fool-proof housing in FIG. 2. Each of the connecting parts 122 includes five second guiding components 120. In this embodiment, the second guiding component 120 is an elongated hole. Each of the elongated holes includes a first positioning end 120a and a second positioning end 120b opposite to each other, and a distance between the first positioning end 120a and the second positioning end 120b is substantially equal to the distance between the first fixing hole 11c and the second fixing hole 11d. The neck portion 1102 of the first guiding component 110 is movably disposed in the second guiding component 120. When the fool-proof element 12 is in the first position, the neck portion 1102 is located at the first positioning end 120a. When the fool-proof element 12 is in the second position, the neck portion 1102 is located at the second positioning end 120b. The head portion 1101 interference with the connecting part 122, preventing the second guiding component 120 from being moved away from the first guiding component 110. The first guiding components 110 respectively correspond to the second guiding components 120. When the fool-proof element 12 is moved between the first position and the second position, the first guiding components 110 are moved relative to the second guiding components 120.

Note that the quantities of the first guiding components 110 and the second guiding components 120 are not restricted and may be increased or decreased in other embodiments, and may not be limited to correspond to the quantities and locations of the accommodation chambers 11a and the accommodation chambers 11b. Furthermore, in other embodiments, the first guiding component may be the elongated hole, and the second guiding component may include the head portion and the neck portion connected to each other.

Note that the quantity of the fool-proof protrusions of each fool-proof element is not restricted and can be changed according to the quantity of the accommodation chambers in each row.

In this embodiment, the second guiding component 120 respectively corresponds to the first guiding components 110, the fool-proof protrusions 123 respectively correspond to the first guiding components 110, and the fool-proof protrusions 123 respectively correspond to the accommodation chambers 11a and 11b. Therefore, relative positions of the fool-proof protrusions 123 relative to corresponding accommodation chambers 11a and 11b are ensured to be substantially consistent, and the stability of the fool-proof elements 12 with respect to the casing 11 can be ensured. However, the present disclosure is not limited thereto.

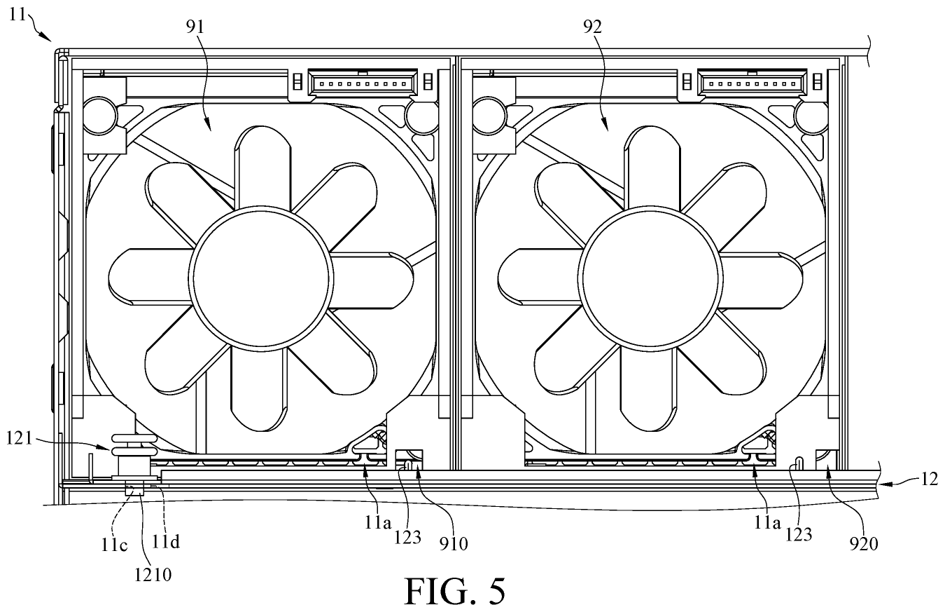

Please refer to FIG. 5, which shows a partial front view of an upper row of the fool-proof housing in FIG. 1 when a first mounting piece is installed on the fool-proof housing. Before installing the first mounting piece 91 into the upper space of the casing 11, the fool-proof element 12 in the upper space should be moved to the first position and then the fixing protrusion 1210 of the fixing part 121 is engaged in the first fixing hole 11c on the transverse carrier plate 113 in the upper space of the casing 11.

The left half of FIG. 5 shows that the first mounting piece 91 is disposed in the accommodation chamber 11a of the casing 11, and the fool-proof protrusion 123 is located in the first fool-proof recess 910 of the first mounting piece 91. With such configuration, during the installation of the first mounting piece 91, the first mounting piece 91 can be inserted into the accommodation chamber 11a without being blocked by the fool-proof protrusion 123.

The right half of FIG. 5 shows that the second mounting piece 92 is attempted to be disposed in the accommodation chamber 11a of the casing 11, but, as can be seen, the fool-proof protrusion 123 does not correspond to the second fool-proof recess 920 of the second mounting piece 92. As such, the fool-proof protrusion 123 blocks the second mounting piece 92 during the insertion of the second mounting piece 92 toward the accommodation chamber 11a, such that the second mounting piece 92 cannot be completely inserted into the accommodation chamber 11a. As a result, the second mounting piece 92 is not allowed to be installed into the accommodation chamber 11a.

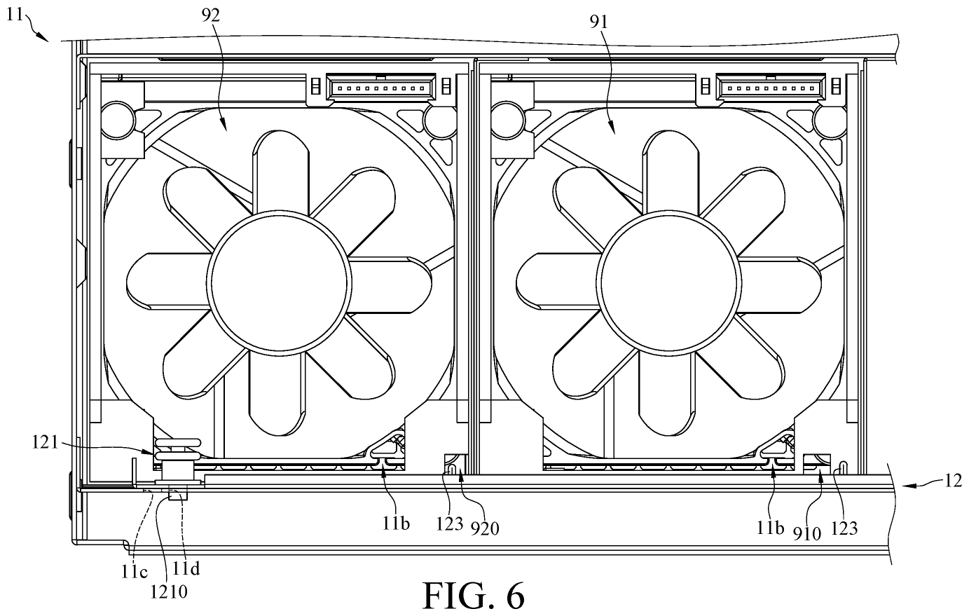

Please refer to FIG. 6, which shows a partial front view of a lower row of the fool-proof housing in FIG. 1 when a second mounting piece is installed on the fool-proof housing. Before installing the second mounting piece 92 into the lower space of the casing 11, the fool-proof element 12 in the lower space should be moved to the second position and then the fixing protrusion 1210 of the fixing part 121 is engaged in the second fixing hole 11d on the transverse carrier plate 113 in the lower space of the casing 11.

The left half of FIG. 6 shows that the second mounting piece 92 is disposed in the accommodation chamber 11b of the casing 11, and the fool-proof protrusion 123 is located in the second fool-proof recess 920 of the second mounting piece 92. With such configuration, during the installation of the second mounting piece 92, the second mounting piece 92 can be inserted into the accommodation chamber 11b without being blocked by the fool-proof protrusions 123.

The right half of FIG. 6 shows that the first mounting piece 91 is attempted to be disposed in the accommodation chamber 11b of the casing 11, but, as can be seen, the fool-proof protrusion 123 does not correspond to the first fool-proof recess 910 of the first mounting piece 91. As such, the fool-proof protrusion 123 blocks the first mounting piece 91 during the insertion of the first mounting piece 91 toward the accommodation chamber 11b, such that the first mounting piece 91 cannot be completely inserted into the accommodation chamber 11b. As a result, the first mounting piece 91 is not allowed to be installed into the accommodation chamber 11b.

As the fool-proof housing discussed above, moving the fool-proof element between the first position and the second position is able to change the locations of the fool-proof protrusions and thus able to selectively allow the installation of one of the first and second mounting pieces but become an obstacle to the installation of the other one of the first and second mounting pieces. Therefore, the fool-proof housing is able to install either the first mounting pieces or the second mounting pieces. That is, the fool-proof housing is compatible with the mounting pieces in different specification, thereby reducing the stock of the housing.

The embodiments were chosen and described in order to best explain the principles of the disclosure and its practical applications, to thereby enable others skilled in the art to best utilize the disclosure and various embodiments with various modifications as are suited to the particular use contemplated. It is intended that the scope of the disclosure be defined by the following claims and their equivalents.

What is claimed is:

1. A fool-proof housing, configured for a first mounting piece or a second mounting piece to be disposed thereon, the first mounting piece comprising a first fool-proof recess, the second mounting piece comprising a second fool-proof recess, and the fool-proof housing comprising:
a casing; and
a fool-proof element, comprising a fool-proof protrusion, wherein the fool-proof element is movably disposed on the casing and the fool-proof element comprises a first position and a second position; when the fool-proof element is in the first position, the casing is configured for the first mounting piece to be mounted thereon, the fool-proof protrusion is located in the first fool-proof recess as the first mounting piece is mounted on the casing, and the fool-proof protrusion blocks the second mounting piece from being mounted on the casing; when the fool-proof element is in the second position, the casing is configured for the second mounting piece to be mounted thereon, the fool-proof protrusion is located in the second fool-proof recess as the second mounting piece is mounted on the casing, and the fool-proof protrusion blocks the first mounting piece from being mounted on the casing.

2. The fool-proof housing according to claim 1, wherein the fool-proof element further comprises a fixing part, the fixing part comprises a fixing protrusion, and the fool-proof element is disposed on the casing via the fixing protrusion.

3. The fool-proof housing according to claim 2, wherein the casing comprises a first fixing hole and a second fixing hole; when the fool-proof element is in the first position, the fixing protrusion is engaged in the first fixing hole; when the fool-proof element is in the second position, the fixing protrusion is engaged in the second fixing hole.

4. The fool-proof housing according to claim 1, wherein the casing comprises a first guiding component, the fool-proof element comprises a second guiding component, the first guiding component and the second guiding component correspond to each other; when the fool-proof element is moved between the first position and the second position, the first guiding component is moved relative to the second guiding component.

5. The fool-proof housing according to claim 4, wherein one of the first guiding component and the second guiding component is an elongated hole, the other of the first guiding component and the second guiding component comprises a head portion and a neck portion connected to each other, and the neck portion is movably disposed in the elongated hole.

6. The fool-proof housing according to claim 5, wherein the elongated hole comprises a first positioning end and a second positioning end; when the fool-proof element is in the first position, one of the first guiding component and the second guiding component is disposed at the first positioning end; when the fool-proof element is in the second position, one of the first guiding component and the second guiding component is disposed at the second positioning end.

7. The fool-proof housing according to claim 6, wherein the fool-proof element further comprises a fixing part, the fixing part comprises a fixing protrusion, the fool-proof element is disposed on the casing via the fixing protrusion, the casing comprises a first fixing hole and a second fixing hole; when the fool-proof element is in the first position, the fixing protrusion is engaged in the first fixing hole; when the fool-proof element is in the second position, the fixing protrusion is engaged in the second fixing hole; a distance between the first positioning end and the second positioning end is substantially equal to a distance between the first fixing hole and the second fixing hole.

8. The fool-proof housing according to claim 1, wherein the fool-proof element further comprises a connecting part connected to the fool-proof protrusion.

9. The fool-proof housing according to claim 8, wherein the casing comprises at least one accommodation chamber, the fool-proof protrusion is disposed on the connecting part and corresponds to the at least one accommodation chamber, the at least one accommodation chamber is configured to accommodate the first mounting piece or the second mounting piece.

10. The fool-proof housing according to claim 9, wherein the quantity of the at least one accommodation chamber is plural, the casing comprises an outer frame and a separation plate, and the separation plate is disposed on the outer frame and separates the plurality of accommodation chambers.
